(19) United States
(12) Patent Application Publication
(10) Pub. No.: US 2013/0069127 A1
(43) Pub. Date: Mar. 21, 2013

(54) FIELD EFFECT TRANSISTOR AND FABRICATION METHOD THEREOF

(71) Applicants: Ho Kyun AHN, Daejeon (KR); Jong-Won Lim, Daejeon (KR); Sung Bum Bae, Daejeon (KR); Sang Choon Ko, Daejeon (KR); Young Rak Park, Daejeon (KR); Woo Jin Chang, Daejeon (KR); Jae Kyoung Mun, Daejeon (KR); Eun Soo Nam, Daejeon (KR); Jeong Jin Kim, Jeonju-si (KR); Chull Won Ju, Daejeon (KR)

(72) Inventors: Ho Kyun AHN, Daejeon (KR); Jong-Won Lim, Daejeon (KR); Sung Bum Bae, Daejeon (KR); Sang Choon Ko, Daejeon (KR); Young Rak Park, Daejeon (KR); Woo Jin Chang, Daejeon (KR); Jae Kyoung Mun, Daejeon (KR); Eun Soo Nam, Daejeon (KR); Jeong Jin Kim, Jeonju-si (KR); Chull Won Ju, Daejeon (KR)

(73) Assignee: ELECTRONICS AND TELECOMMUNICATIONS RESEARCH INSTITUTE, Daejeon (KR)

(21) Appl. No.: 13/556,377

(22) Filed: Jul. 24, 2012

(30) Foreign Application Priority Data
Sep. 21, 2011 (KR) 10-2011-0095260
Jun. 12, 2012 (KR) 10-2012-0062664

(51) Int. Cl. H01L 29/78; H01L 21/20

(52) U.S. Cl. 257/288; 438/478; 257/E21.09; 257/E29.255

(57) ABSTRACT

A method for fabricating a field effect transistor according to an exemplary embodiment of the present disclosure includes: forming an active layer, a cap layer, an ohmic metal layer and an insulating layer on a substrate; forming multilayered photoresists on the insulating layer; patterning the multilayered photoresists to form a photoresist pattern including a first opening for gate electrode and a second opening for field electrode; etching the insulating layer by using the photoresist pattern as an etching mask so that the insulating layer in the first opening is etched more deeply and the cap layer is exposed through the first opening; etching the cap layer exposed by etching the insulating layer through the first opening to form a gate recess region; and depositing a metal on the gate recess region and the etched insulating layer to form a gate-field electrode layer.

### CROSS-REFERENCE TO RELATED APPLICATIONS

This application is based on and claims priority from Korean Patent Application No. 10-2011-0095260, filed on Sep. 21, 2011, and Korean Patent Application No. 10-2012-0062664, filed on Jun. 12, 2012, with the Korean Intellectual Property Office, the present disclosure of which is incorporated herein in its entirety by reference.

### TECHNICAL FIELD

The present disclosure relates to a field effect transistor including a field electrode and a fabrication method thereof.

### BACKGROUND

FIGS. 1A to 1E are views for describing a method for fabricating a field effect transistor by a technology in the related art.

First, as illustrated in FIG. 1A, an active layer 11 and a cap layer 12 are sequentially formed on a compound semiconductor such as gallium nitride (GaN), silicon (Si), silicon carbide (SiC), or a semi-insulating gallium arsenide (GaAs) and the like, or another semiconductor substrate 10. For example, in the case of a high electron mobility transistor (HEMT) device using a hetero-junction of aluminum gallium nitride (AlGaN) and gallium nitride (GaN), the active layer 11 consists of a gallium nitride buffer layer and an aluminum gallium nitride barrier layer, and the cap layer 12 consists of a gallium nitride (GaN) layer.

Subsequently, as illustrated in FIG. 1B, a region on which an ohmic metal layer 13 constituting source and drain electrodes is to be formed is defined by a photoresist pattern, and then the ohmic metal is deposited thereon, and the metal is subjected to RTA and the like to form the ohmic metal layer 13. For example, in the process of manufacturing a high electron mobility transistor (HEMT) device using a gallium nitride (GaN)-based compound semiconductor, a metal layer on which a Ti/Al/Ni/Au film and the like are sequentially deposited to a predetermined thickness may be used as the ohmic metal, and when a device such as a high electron mobility transistor (HEMT) using other gallium arsenide (GaAs)-based compound semiconductors, a metal semi-conductor field effect transistor (MESFET) and the like is manufactured, a metal layer on which an AuGe film, an Ni film, an Au film and the like are sequentially deposited to a predetermined thickness may be used as the ohmic metal.

Subsequently, an insulating layer 14 is deposited on a substrate on which the ohmic process has been completed as illustrated in FIG. 1C, a photoresist 15 is applied thereon as illustrated in FIG. 1D, and a gate pattern 16a is formed by using photolithography, electron beam lithography or the like.

Subsequently, a process of etching the insulating layer 14 exposed through the gate pattern 16a as illustrated in FIG. 1E is performed to form an opening 16b on the insulating layer 14 in which a gate terminal of the gate electrode is to be formed, and the photoresist 15 is removed as illustrated in FIG. 1F.

Subsequently, a photoresist 17 of the gate head pattern, which is larger than the opening 16b defined by the gate pattern and extends to the drain region, is formed as illustrated in FIG. 1G, and a gate recess process is performed as illustrated in FIG. 1H to form a gate recess region 16c on which a gate metal is to be deposited. The gate recess process is a very important process step in a device such as HEMT, MESFET and the like using a compound semiconductor, is typically performed while current is measured, and may be performed in a single step or multiple steps such as a wet step, a dry step, a combination of dry and wet steps and the like. The gate recess process may be performed by using gas such as CF₄, BCl₃, Cl₂, SF₆ and the like in dry etching equipment such as electron cyclotron resonance (ECR), inductive coupled plasma (ICP) and the like, and may also be performed with various wet etching solutions such as a phosphoric acid-based solution, in which H₃PO₄, H₂O₂, H₂O and the like which are applied to a gallium arsenide (GaAs)-based compound semiconductor device are mixed at an appropriate ratio, and the like.

Subsequently, as illustrated in FIG. 1I, a gate metal is deposited on the gate pattern, the photoresist 17 is removed through the lift-off process, and a γ-type gate electrode, in which the gate head region extends to the drain region, is formed. In the process of manufacturing a HEMT device using a gallium nitride (GaN)-based compound semiconductor, a metal layer in which an Ni film and an Au film are sequentially deposited to a predetermined thickness may be used as a gate electrode 18, and when a device such as HEMT, MESFET and the like using a gallium arsenide (GaAs)-based compound semiconductor is manufactured, a metal layer such as a Ti film, a Pt film, an Au film and the like may be sequentially deposited to a predetermined thickness to manufacture the gate electrode 18.

FIGS. 2A to 2E are views for describing a method for fabricating a field effect transistor by another technology in the related art.

First, as illustrated in FIGS. 2A and 2B, an active layer 21, a cap layer and an ohmic metal layer are sequentially formed on a semiconductor substrate 20. This is the same as what is described in FIGS. 1A and 1B.

Subsequently, as illustrated in FIG. 2C, multilayered photoresists 24a, 24b and 24c are applied on a substrate on which the ohmic process has been completed, and a T-type gate pattern 25a is formed by using photolithography, electron beam lithography or the like. The T-type gate is used in order to reduce the width of the gate without increasing the resistance of the gate electrode.

Subsequently, as illustrated in FIG. 2D, the gate recess process of etching the cap layer 22 exposed on the T-type gate pattern 25a is performed to form a gate recess region 25b on which a gate metal is to be deposited.

Subsequently, as illustrated in FIG. 2E, a gate metal is deposited on the gate pattern, and the photoresists 24a, 24b and 24c are removed through the lift-off process to form a T-type gate electrode 26. At this time, in the process of manufacturing a HEMT device using a gallium nitride (GaN)-based compound semiconductor, a metal layer in which an Ni film and an Au film are sequentially deposited to a predetermined thickness may be used as a T-type gate electrode 26, and when a device such as HEMT, MESFET and the like using a gallium arsenide (GaAs)-based compound semiconductor is manufactured, a metal layer such as a Ti film, a Pt film, an Au film and the like may be sequentially deposited to a predetermined thickness to manufacture the T-type gate electrode 26.

Subsequently, an insulating layer 27 is deposited on the substrate on which the T-type gate electrode 26 is formed as illustrated in FIG. 2F, and as illustrated in FIG. 2G, a photoresist pattern 28 for forming an electric field is formed through the lithography process.

Subsequently, as illustrated in FIG. 2H, a metal is deposited on the insulating layer 27 through the photoresist pattern 28 to form a field electrode 29, and a lift-off process is performed to remove the photoresist.

In this case, the thickness of the insulating layer 27 may be controlled by controlling the degree of overetching in the insulating layer etching process, but a separate mask pattern for manufacturing the field electrode 29 is required, and accordingly, the process is accompanied by lithography, etching, metal deposition, a lift-off process and the like.

When the above-described method in the related art is used, an electric field between gate and drain regions is reduced to decrease a peak value by manufacturing a field electrode, a high breakdown voltage may be obtained by reducing a gate leakage current while maintaining high frequency performance, and thus it is possible to manufacture a power device capable of driving at high voltage and high current. However, in the case of a field effect transistor including the field electrode, the thickness of an insulating layer at the lower portion of the field electrode formed on one substrate is fixed, and as the gate heat extends to the drain region, parasitic components increase and thus high frequency characteristics may be degraded.

Specifically, in the field effect transistor by the first described fabrication method in the related art, the drain direction portion of the gate head serves as a field electrode and the thickness of an insulating layer below the field electrode may not be controlled. In order to control the thickness, a separate mask pattern which defines the field electrode portion is required, and subsequent processes such as lithography process, etching process and the like about the mask pattern need to be repeated. In the field effect transistor by the second described fabrication method, the thickness of an insulating layer below the field electrode may be controlled, but a separate mask pattern for manufacturing a field electrode is required.

For example, in the case of a HEMT device manufactured by using a compound semiconductor such as a GaN, GaAs, InP substrate and the like, a field electrode other than a gate is manufactured between a source and a drain. In this case, the field electrode is manufactured by using a mask pattern for forming a field electrode. The thickness of an insulating layer below the field electrode may be controlled by controlling the insulating layer etching process, but a separate mask pattern for manufacturing a field electrode is added, and metal deposition and lift-off processes need to be repeated.

That is, in the case of a fabrication method of a field effect transistor including a field electrode by a technology in the related art, a separate mask pattern is required in order to control the thickness of the insulating layer below the field electrode, additional subsequent processes such as lithography process, etching process and the like need to be repeated for each mask pattern, and thus there is a problem in that the fabrication cost is increased and the productivity is deteriorated.

### SUMMARY

The present disclosure has been made in an effort to provide a field effect transistor which may reduce the fabrication cost and improve the stability and productivity of a device by forming a field electrode without a separate lithography process and accompanying additional process steps, and a fabrication method thereof.

An exemplary embodiment of the present disclosure provides a method for fabricating a field effect transistor, including: sequentially forming an active layer, a cap layer, an ohmic metal layer and an insulating layer on a substrate; forming multilayered photoresists on the insulating layer; patterning the multilayered photoresists to form a photoresist pattern including a first opening for gate electrode and a second opening for field electrode; using the photoresist pattern as an etching mask to etch the insulating layer, the insulating layer in the first opening etched more deeply such that the cap layer is exposed through the first opening; etching the cap layer exposed by etching the insulating layer through the first opening to form a gate recess region; and depositing a metal on the gate recess region and the etched insulating layer to form a gate-field electrode layer.

In the forming of the photoresist pattern, the multilayered photoresists may be patterned such that the insulating layer is exposed through the first opening and the lowermost photoresist of the multilayered photoresists is exposed through the second opening.

When the insulating layer is etched, the type and thickness of the multilayered photoresists may be selected by considering an etching selectivity such that the insulating layer may be all exposed in a region in which the lowermost photoresist and the photoresist at the upper layer thereof in the photoresist pattern are exposed.

The gate-field electrode layer may be simultaneously formed as one metal layer.

Another exemplary embodiment of the present disclosure provides a field effect transistor, including: a substrate; an active layer formed on the substrate; a cap layer formed on the active layer and exposing the active layer to the upper portion thereof due to a gate recess region formed on some portions thereof; an ohmic metal layer formed as an ohmic metal layer at both sides on the cap layer to function as source and drain electrodes; an insulating layer formed on the cap layer and the ohmic metal layer exposing the gate recess region to the upper portion thereof due to an etch hole formed on the upper portion of the gate recess region, and having an etch pit formed adjacent to the etch hole ; and a gate-field electrode layer formed on the insulating layer in a form that the gate recess region, the opening, the etch hole and the etch pit are filled with one metal layer.

According to the present disclosure, during the insulating layer etching process, characteristics of the field electrode may be controlled by controlling the thickness of an insulating layer below a portion on which a field electrode is to be formed, and a power device capable of reducing a peak value of an electric field, improving breakdown voltage characteristics of the device, reducing a leakage current and obtaining high power when the device drives at high voltage may be manufactured.

A relatively wide gate head portion may be kept farther from a substrate than the field electrode and the field electrode may be kept closer to the substrate than the gate head portion to prevent high frequency characteristics from being degraded due to parasitic components by the field electrode in a field effect transistor including the field electrode.

A separate additional mask for forming a field electrode is not required, and thus it is possible to improve productivity and manufacture a transistor, which is more homogeneous and reproducible than transistors produced by a process in the related art and has excellent performance.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A to 1E are views for describing a method for fabricating a field effect transistor by a technology in the related art.

FIGS. 2A to 2E are views for describing a method for fabricating a field effect transistor by another technology in the related art.

FIGS. 3A to 3G are views for describing a method for fabricating a field effect transistor according to an exemplary embodiment of the present disclosure.

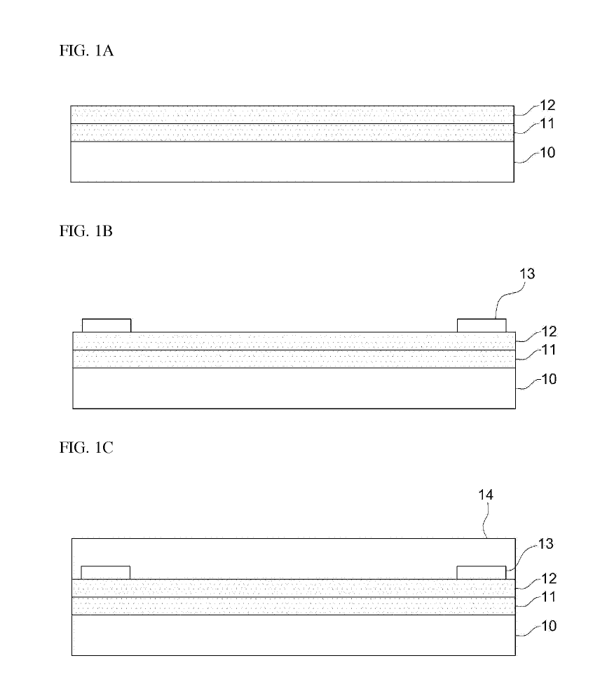

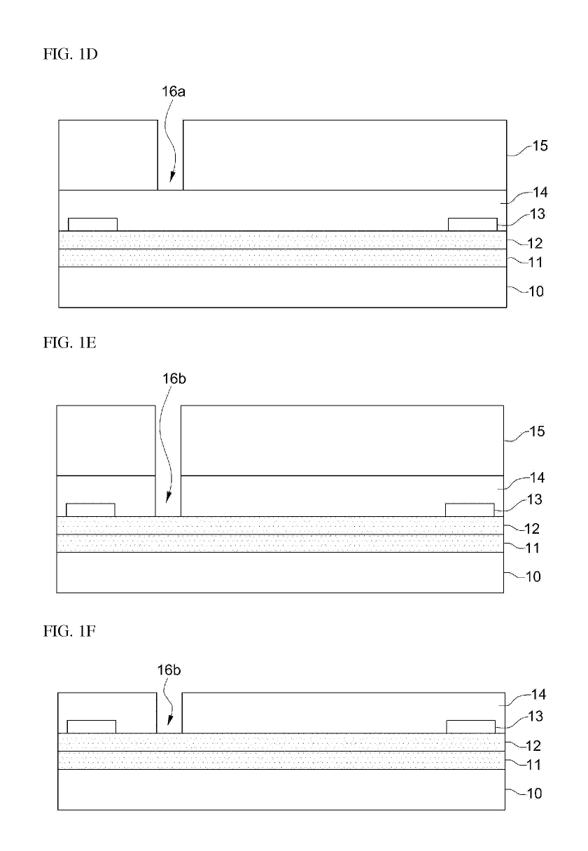

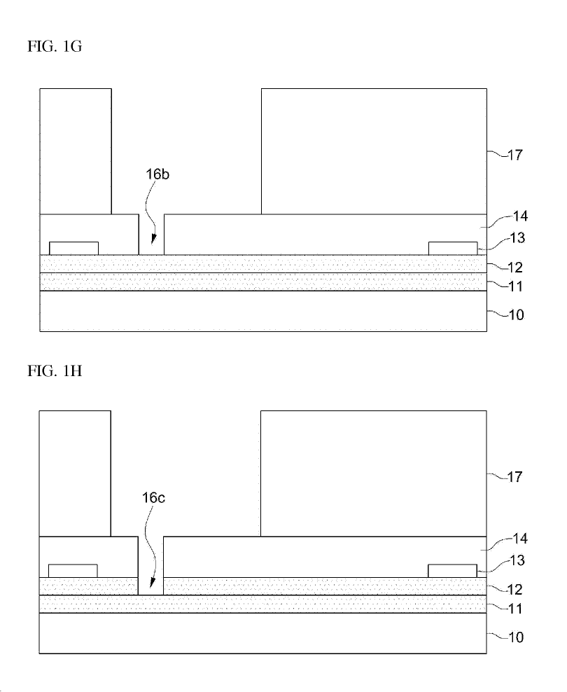

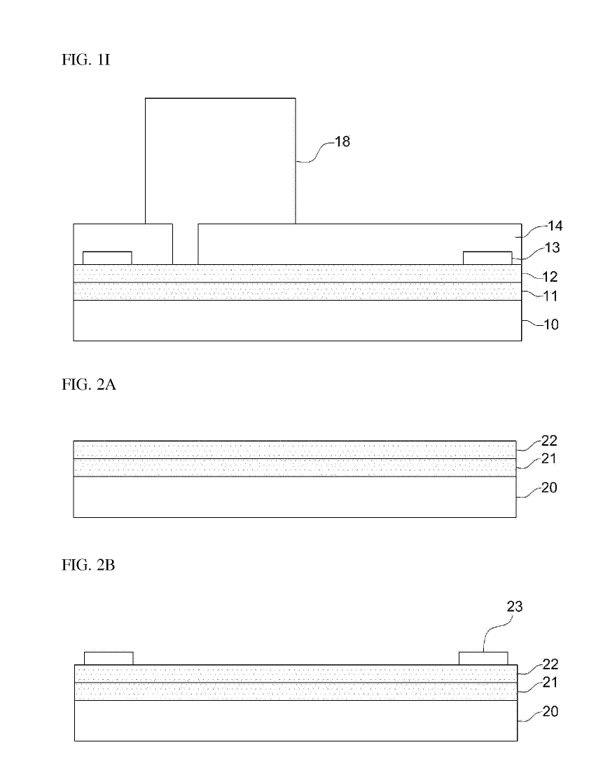

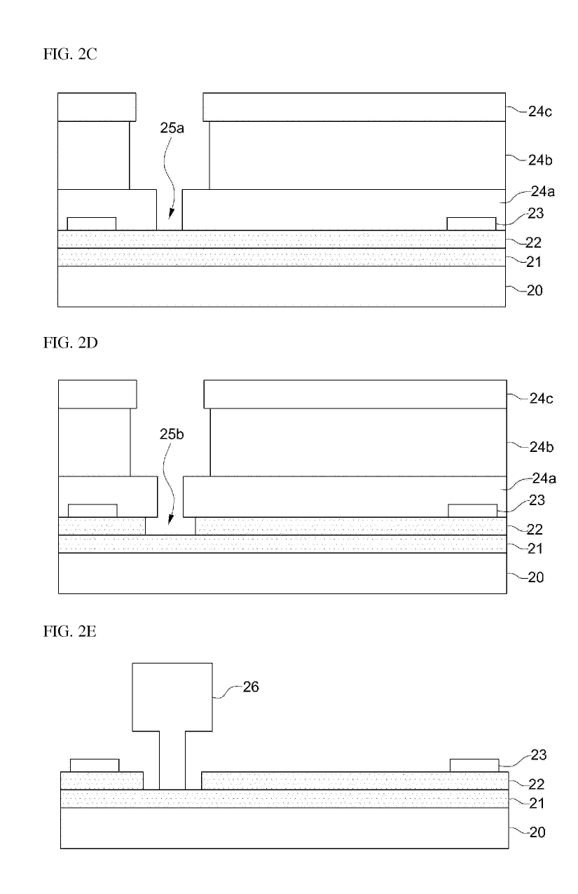

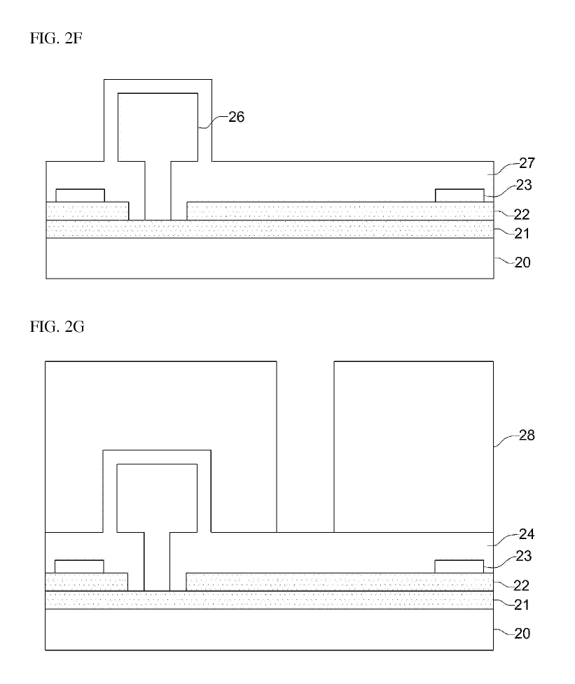

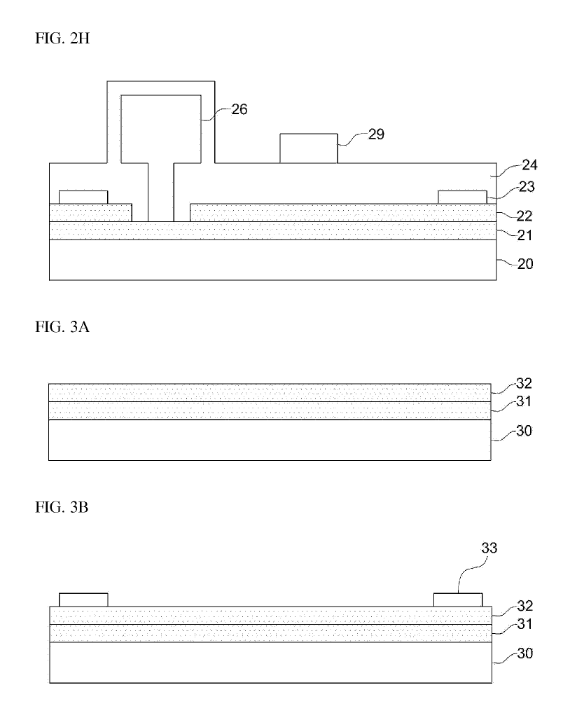

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The above-described objects, features and advantages will be described below in detail with reference to the accompanying drawings, and accordingly the technical spirit of the present disclosure may be easily implemented by those having ordinary skill in the art. In describing the present disclosure, when it is judged that specific description about known technologies related to the present disclosure may unnecessarily obscure the essentials of the present disclosure, the detailed description will be omitted. Hereinafter, preferred embodiments according to the present disclosure will be described in detail with reference to the accompanying drawings.

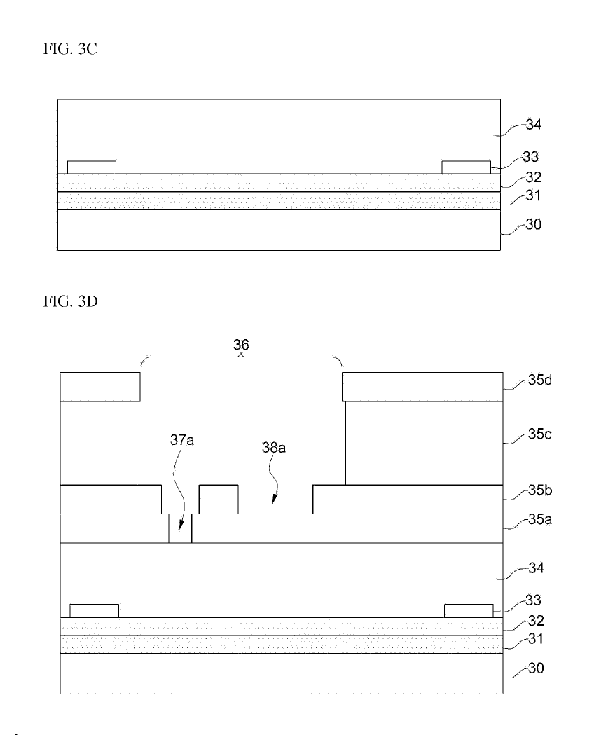

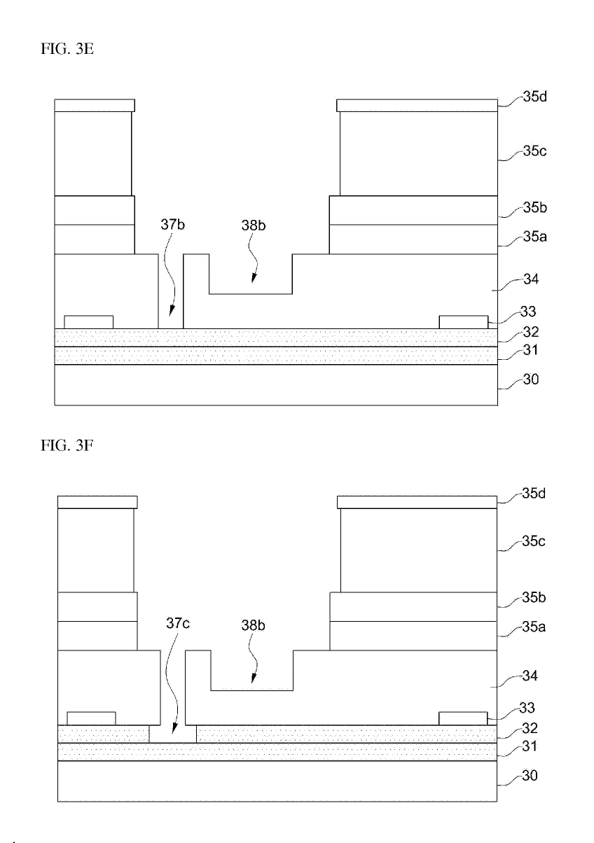

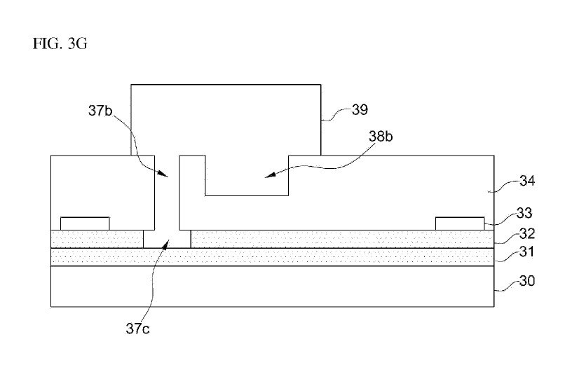

FIGS. 3A to 3G are views for describing a method for fabricating a field effect transistor according to an exemplary embodiment of the present disclosure.

Referring to FIGS. 3A to 3G, the method for fabricating a field effect transistor according to an exemplary embodiment of the present disclosure includes: sequentially forming an active layer 31, a cap layer 32, an ohmic metal layer 33 and an insulating layer on a substrate 30, forming multilayered photoresists 35a to 35d on the insulating layer 34, patterning the multilayered photoresists to form photoresist patterns 35a to 35d including a first opening 37a for gate electrode and a second opening 38a for field electrode, using the photoresist patterns 35a to 35d as an etching mask to etch the insulating layer 34, the insulating layer 34 in the first opening 37a etched more deeply such that the cap layer 32 is exposed through the first opening 37a, etching the cap layer 32 exposed by etching the insulating layer 34 through the first opening 37a to form a gate recess region 37c; and depositing a metal on the gate recess region 37c and the etched insulating layer 34 to form a gate-field electrode layer 39.

First, the active layer 31 and the cap layer 32 are formed on the semiconductor substrate 30 as illustrated in FIG. 3A, and as illustrated in FIG. 3B, a region in which source and drain electrodes are to be formed is defined by a photoresist pattern (not illustrated in the drawing), then an ohmic metal is deposited thereon and the metal is subjected to rapid thermal annealing (RTA) and the like to form an ohmic metal layer 33 constituting the source and drain electrodes. At this time, in the process of manufacturing an HEMT device using a GaN-based compound semiconductor, a metal layer in which Ti, Al, Ni Au films and the like are sequentially deposited to a predetermined thickness may be used as an ohmic metal, and when a device such as HEMT, MESFET and the like using other GaAs-based compound semiconductors is manufactured, a metal layer in which AuGe, Ni, Au films and the like are sequentially deposited to a predetermined thickness may be used as an ohmic metal.

Subsequently, as illustrated in FIG. 3C, a single-layered or multilayered insulating layer 34 is deposited on a substrate on which the ohmic process has been completed. At this time, the insulating layer 34 may be formed of a material such as silicon nitrides, silicon oxides, BCB, other porous silica thin films and the like, and has a function of protecting the surface of the compound semiconductor substrate. The type and thickness of the insulating layer is determined by considering the etch rates of the photoresists at the lowermost layer and the upper layer thereof in the multilayered photoresists formed in the subsequent process and the etch rate of the insulating layer 34.

Subsequently, as illustrated in FIG. 3D, multilayered photoresists are coated on the substrate on which the insulating layer 34 is deposited, and photoresist patterns 35a to 35d having different exposure layers of the openings 37a and 38a are formed. In the exemplary embodiment, a four-layered photoresist is used, and for example, when electron beam lithography is used, various combinations of photoresist layers such as PMMA/PMGI/Copolymer/PMMA, ZEP/PMGI/Copolymer/ZEP and the like may be used (it is obvious that the number and material of the photoresists may vary depending on the case). The photoresist patterns 35a to 35d are formed such that the exposure layer of the first opening 37a is the insulating layer 34 and the exposure layer of the second opening 38a is the lowermost photoresist (hereinafter, referred to as a first photoresist) 35a. At this time, it is necessary to select the type and thickness of the first photoresist 35a and the photoresist (hereinafter, referred to as a second photoresist) 35b at the upper layer thereof by considering the etching selectivity such that the insulating layer 34 may all be exposed in a region 36 in which the first and second photoresists 35a and 35b are exposed during the subsequent insulating layer etching process.

Subsequently, as illustrated in FIG. 3E, the photoresist patterns 35a to 35d are used as an etching mask to perform a process of etching an insulating layer 34. The etching process may be performed by a dry etching method such as reactive ion etching (RIE), magnetically enhanced reactive ion etching (MERIE), inductive coupled plasma (ICP) and the like.

When the etching process is specifically examined, the insulating layer 34 is all etched through the first opening 37a of the photoresist patterns 35a to 35d to form an etch hole 37b, and some of the upper portions of the first photoresist 35a and the insulating layer 34 are etched through the second opening 37b to form an etch pit 38b. At this time, in order to simultaneously form a gate electrode and a field electrode in a subsequent process, it is preferred that exposed portions of the first and second photoresists 35a and 35b are all etched in the region 36 in which the first and second photoresists 35a and 35b are exposed by the wide opening at the uppermost layer in the photoresist patterns 35a to 35d.

Subsequently, as illustrated in FIG. 3F, some of the cap layer 32 exposed through the etch hole 37b is etched to form a gate recess region 37c on which a gate electrode metal is to be deposited. The gate recess process is a very important process step in a process of fabricating a device such as HEMT, MESFET and the like using a compound semiconductor, and is generally carried out while current is measured. The gate recess process may be performed by a etching method using drying, wetting or a combination of drying and wetting, and may be performed by using a dry etching gas including at least one of CF₄, B Cl₃, Cl₂ and SF₆ in dry etching equipment such as electron cyclotron resonance (ECR), inductive coupled plasma (ICP) and the like, or performed by using various wet etching solutions such as a phosphoric acid-based solution and the like in which H₃PO₄, H₂O₂, H₂O and the like are mixed at an appropriate ratio.

Subsequently, as illustrated in FIG. 3G, a metal is deposited on the etch hole 37b, the etch pit 38b and the recess region 37c formed at the insulating layer to form a gate-field metal layer 39, and the photoresist patterns 35a to 35d remaining are removed through the lift-off process.

The gate electrode and the field electrode may be simultaneously formed without a separate additional process in this manner, and the thickness of the insulating layer below the field electrode may be controlled during the process of etching the insulating layer 34. Therefore, a power device capable of improving breakdown voltage characteristics of the device, reducing a leakage current and obtaining high power when the device drives at high voltage may be manufactured. A separate additional mask for forming a field electrode is not required, and thus it is possible to improve productivity and manufacture a transistor, which is more homogeneous and reproducible than transistors produced by a process in the related art and has excellent performance.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for fabricating a field effect transistor, comprising:
forming an active layer, a cap layer, an ohmic metal layer and an insulating layer on a substrate;
forming multilayered photoresists on the insulating layer;
patterning the multilayered photoresists to form a photoresist pattern comprising a first opening for gate electrode and a second opening for field electrode;
etching the insulating layer by using the photoresist pattern as an etching mask so that the insulating layer in the first opening is etched more deeply and the cap layer is exposed through the first opening;
etching the cap layer exposed by etching the insulating layer through the first opening to form a gate recess region; and
depositing a metal on the gate recess region and the etched insulating layer to form a gate-field electrode layer.

2. The method of claim 1, wherein in the forming of the photoresist pattern, the multilayered photoresists are patterned such that the insulating layer is exposed through the first opening and the lowermost photoresist of the multilayered photoresists is exposed through the second opening.

3. The method of claim 2, wherein when the insulating layer is etched, the type and thickness of the multilayered photoresists is selected by considering an etching selectivity such that the insulating layer is all exposed in a region in which the lowermost photoresist and the photoresist at the upper layer thereof in the photoresist pattern are exposed.

4. The method of claim 1, wherein the gate-field electrode layer is simultaneously formed as one metal layer.

5. The method of claim 1, wherein the insulating layer is formed of a material comprising at least one of silicon nitride, silicon oxide, HfO₂, BCB and silica gel.

6. The method of claim 1, wherein the multilayered photoresists are formed of four layers and formed in a combined form of PMMA/PMGI/Copolymer/PMMA or ZEP/PMGI/Copolymer/ZEP.

7. The method of claim 1, wherein the forming of the gate recess region is performed by a etching method using drying, wetting or a combination of drying and wetting.

8. The method of claim 7, wherein the forming of the gate recess region is performed by using a dry etching gas comprising at least one of CF₄, BCl₃, Cl₂ and SF₆ or performed by using a wet etching solution comprising at least one of H₃PO₄, H₂O₂, H₂O.

9. The method of claim 1, further comprising removing a photoresist pattern remaining through a lift-off process after the gate electrode and the field electrode are formed.

10. A field effect transistor comprising:
a substrate;
an active layer formed on the substrate;
a cap layer formed on the active layer and exposing the active layer to the upper portion thereof due to a gate recess region formed on some portions thereof;
an ohmic metal layer formed as an ohmic metal layer at both sides on the cap layer to function as source and drain electrodes;
an insulating layer formed on the cap layer and the ohmic metal layer and exposing the gate recess region to the upper portion thereof due to an etch hole formed on the upper portion of the gate recess region, and having an etch pit formed adjacent to the etch hole; and
a gate-field electrode layer formed on the insulating layer in a form that the gate recess region, the opening, the etch hole and the etch pit are filled with one metal layer.
